(19) United States
(12) Patent Application Publication
(10) Pub. No.: US 2022/0041799 A1
(43) Pub. Date: Feb. 10, 2022

(54) WHITE-LIGHT BLOCK POLYMER, INK COMPOSITION, AND MANUFACTURING METHOD THEREOF

(71) Applicant: Shenzhen China Star Optoelectronics Semiconductor Display Technology Co., Ltd., Shenzhen, Guangdong (CN)

(72) Inventor: Shijie ZHANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/759,747

(22) PCT Filed: Mar. 23, 2020
(86) PCT No.: PCT/CN2020/080557

§ 371 Date: Apr. 28, 2020

(30) Foreign Application Priority Data
Mar. 4, 2020 (CN) 202010142372.3

(51) Int. Cl. C08G 61/12; C09D 11/033; C09D 11/102; C09D 11/38; C08K 5/3415; C08K 5/13

(52) U.S. Cl. CPC C08G 61/126; C09D 11/033; C09D 11/102; C09D 11/38; C08K 5/3415; C08G 2261/126; C08G 2261/1412; C08G 2261/3142; C08G 2261/3223; C08G 2261/3229; C08K 5/13

(57) ABSTRACT

The present disclosure provides a white-light block polymer, an ink composition, and a manufacturing method thereof. The white-light block polymer makes it only necessary to print one ink when using inkjet printing, thereby simplifying inkjet printing processing and meanwhile preventing a crosstalk problem of pixels having different colors of light. The present disclosure makes the ink composition suitable for inkjet printing by properly mixing the white-light block polymer, an organic solvent, a surface tension modifier, and a viscosity modifier in a suitable ratio.

### FIELD OF INVENTION

The present disclosure relates to the field of organic light-emitting diode technologies, and more particularly, to a white-light block polymer, an ink composition, and a manufacturing method thereof.

### BACKGROUND OF INVENTION

As manufacturing of organic light-emitting diode (OLED) devices by solution processing, especially by inkjet printing, has advantages of low cost, no metal mask requirement, and high material utilization during manufacturing processes of panels having a large area, the manufacturing of OLED devices by solution processing has increasingly received more attention.

In general, OLED devices comprise multiple layers of structures, such as a hole transport layer (HTL), a light emitting layer (EML), and an electron transport layer (ETL). Wherein, the light emitting layer usually comprises a red-light organic light-emitting layer, a blue-light organic light-emitting layer, and a green-light organic light-emitting layer. Because the red-light organic light-emitting layer, the blue-light organic light-emitting layer, and the green-light organic light-emitting layer use three different inks, they need to be printed separately when using inkjet printing, which increases processing complexity. Furthermore, even when a highly precise printing device is used, a crosstalk problem still exists in organic light-emitting layers which emit different light, which further causes pixels to emit light abnormally.

Technical problem: an objective of the present disclosure is to provide a white-light block polymer, an ink composition, and a manufacturing method thereof to solve the crosstalk problem existing when using inkjet printing to print three different colors of inks.

### SUMMARY OF INVENTION

In order to achieve the above objective, an embodiment of the present disclosure provides a white-light block polymer which comprises a yellow-light block or/and a red-light block and a green-light block, and a blue-light block;

wherein the blue-light block is at least one selected from the group consisting of polyfluorene, polyfluorene derivatives, polybenzene, polybenzene derivatives, polycarbazole, and polycarbazole derivatives, the yellow-light block is at least one selected from the group consisting of polybenzothiadiazole and poly(phenylene vinylene), the red-light block is poly(dithiophenebenzothiadiazole), and the green-light block is at least one selected from the group consisting of polybenzothiadiazole and poly(phenylene vinylene).

The above white-light block polymer has a structure shown in a following formula (1),

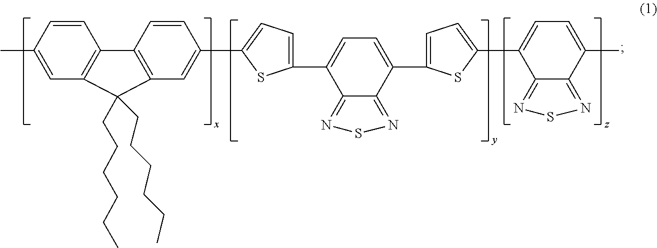

wherein x, y, and z are molar ratios of corresponding polymer main chains to the white-light block polymer, x, y, and z are greater than 0 and less than 1, and x, y, and z satisfy formulas x+y+z=1 and y=x+z.

In the above white-light block polymer, wherein x:y:z=(0.35-0.45):0.5:(0.05-0.15).

In the above white-light block polymer, wherein x:y:z=0.4:0.5:0.1.

In the above white-light block polymer, wherein number average molecular weight of the white-light block polymer ranges from 1000 to 10000.

An ink composition, wherein according to percentages by weight, the ink composition comprises:

0.001% to 10% of the white-light block polymer;

60% to 90% of an organic solvent;

0.01% to 15% of a surface tension modifier; and

0.01% to 15% of a viscosity modifier.

According to percentages by weight, the above ink composition comprises:

0.01% to 5% of the white-light block polymer;

75% to 85% of the organic solvent;

0.1% to 10% of the surface tension modifier; and

0.1% to 10% of the viscosity modifier.

In the above ink composition, wherein the organic solvent is at least one selected from the group consisting of ethylene glycol monobutyl ether acetate, propyleneglycol monoethyl ether, and durene.

In the above ink composition, the surface tension modifier is at least one selected from the group consisting of imidazole, imidazole derivatives, phenol, and hydroquinone.

In the above ink composition, the viscosity modifier is at least one selected from the group consisting of alcohols, ethers, esters, and organic amines.

A manufacturing method of an ink composition comprises following steps:

dissolving 0.001 wt % to 10 wt % of the above white-light block polymer into 60 wt % to 90 wt % of an organic solvent to obtain a first solution; and

adding 0.01 wt % to 15 wt % of a surface tension modifier and 0.01 wt % to 15 wt % of a viscosity modifier into the first solution and mixing uniformly to obtain the ink composition.

The above manufacturing method of the ink composition comprises following steps:

dissolving 0.01 wt % to 5 wt % of the above white-light block polymer into 75 wt % to 85 wt % of the organic solvent to obtain the first solution; and

adding 0.1 wt % to 10 wt % of the surface tension modifier and 0.1 wt % to 10 wt % of the viscosity modifier into the first solution and mixing uniformly to obtain the ink composition.

In the above manufacturing method of the ink composition, the organic solvent is at least one selected from the group consisting of ethylene glycol monobutyl ether acetate, propyleneglycol monoethyl ether, and durene.

In the above manufacturing method of the ink composition, the surface tension modifier is at least one selected from the group consisting of imidazole, imidazole derivatives, phenol, and hydroquinone.

In the above manufacturing method of the ink composition, the viscosity modifier is at least one selected from the group consisting of alcohols, ethers, esters, and organic amines.

Beneficial effect: the present disclosure provides a white-light block polymer, an ink composition, and a manufacturing method thereof. The white-light block polymer makes it only necessary to print one ink when using inkjet printing, thereby simplifying inkjet printing processing and meanwhile preventing the crosstalk problem of pixels having different colors of light. The present disclosure makes the ink composition suitable for inkjet printing by properly mixing the white-light block polymer, an organic solvent, a surface tension modifier, and a viscosity modifier in a suitable ratio.

Further, the present disclosure makes the ink composition more suitable for inkjet printing processing by selecting an organic solvent having a high boiling point.

### DESCRIPTION OF DRAWINGS

FIG. 1 is a synthesis route of a white-light block polymer according to embodiment 1 of the present disclosure.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure. Based on the embodiments in the present disclosure, all other embodiments obtained by those skilled in the art without creative efforts are within the scope of the present disclosure.

An embodiment of the present disclosure provides a white-light block polymer. The white-light block polymer comprises a yellow-light block or/and a red-light block and a green-light block, and a blue-light block.

Wherein, the blue-light block is at least one selected from the group consisting of polyfluorene, polyfluorene derivatives, polybenzene, polybenzene derivatives, polycarbazole, and polycarbazole derivatives, the yellow-light block is at least one selected from the group consisting of polybenzothiadiazole and poly(phenylene vinylene), the red-light block is poly(dithiophenebenzothiadiazole), and the green-light block is at least one selected from the group consisting of polybenzothiadiazole and poly(phenylene vinylene).

The white-light block polymer of the present disclosure at least comprises a specific blue-light block, a specific red-light block, and a specific green-light block; or the white-light block polymer at least comprises a specific blue-light block and a specific yellow-light block to make the white-light block polymer emit white light. When the white-light block polymer is applied to an organic light-emitting diode display, only one ink needs to be printed when using inkjet printing, which simplifies inkjet printing processing, prevents different pixels from risk of crosstalking, and reduces materials of the organic light-emitting diode display and processing cost.

It can be understood that a ratio of each block constituting the white-light block polymer can be adjusted according to actual needs. Flexibility of the white-light block polymer can also be increased by introducing flexible side chains to the white-light block polymer, for example, long alkyl chains. Solubility of the white-light block polymer can also be increased by introducing a side chain having an ammonia positively charged ion to the white-light block polymer to improve solubility of molecules and film-forming ability.

The white-light block polymer has a structure shown in a following formula (1),

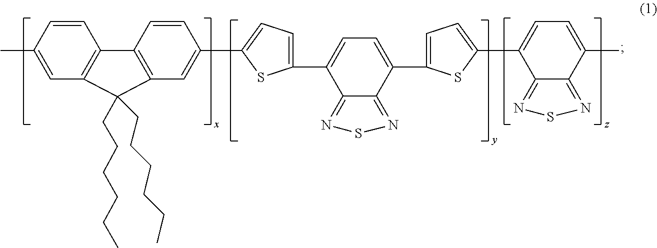

wherein, x, y, and z are molar ratios of corresponding polymer main chains to the white-light block polymer, x, y, and z are greater than 0 and less than 1, and x, y, and z satisfy formulas x+y+z=1 and y=x+z.

Wherein, x:y:z=(0.35-0.45):0.5:(0.05-0.15).

Further, x:y:z=0.4:0.5:0.1.

Wherein, number average molecular weight of the white-light block polymer ranges from 1000 to 10000. Further, the number average molecular weight of the white-light block polymer ranges from 2000 to 8000. For example, the number average molecular weight of the white-light block polymer is 3000, 4000, 5000, or 6000.

Specifically, the above technical solution is further described with reference to specific embodiments below.

### Embodiment 1

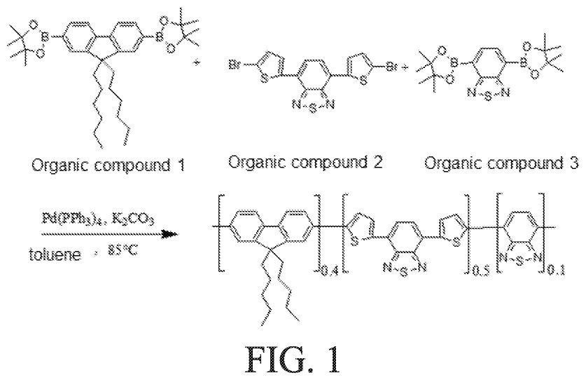

The embodiment provides a white-light block polymer. A synthesis process of the white-light block polymer is as shown in FIG. 1. A manufacturing method of the white-light block polymer comprises following steps:

adding 0.4 mmol of an organic compound 1, 0.5 mmol of an organic compound 2, 0.1 mmol of an organic compound 3, and 2 mmol of potassium carbonate into 70 mL of a solvent, adding 0.1 mmol of tetrakis (triphenylphosphine) palladium as a catalyst under nitrogen environment, then cooling to room temperature after heating to 85° C. for 72 hours for reaction, then after dissolving with chloroform, precipitating for three times in acetone to obtain the white-light block polymer.

### Embodiment 2

The embodiment provides an ink composition. The ink composition comprises 0.001 g of the white-light block polymer obtained from embodiment 1, 90 g of durene, 0.5 g of imidazole, and 9.499 g of ethylenediamine.

A manufacturing method of the ink composition comprises following steps:

adding 0.001 g of the white-light block polymer obtained from embodiment 1 into 90 g of toluene and stirring to obtain a first solution; and

adding 0.5 g of imidazole and 9.499 g of ethylenediamine into the first solution and mixing uniformly to obtain the ink composition.

### Embodiment 3

The embodiment provides an ink composition. The ink composition comprises 9 g of the white-light block polymer obtained from embodiment 1, 61 g of propyleneglycol monoethyl ether, 15 g of phenol, and 15 g of ethanol.

The manufacturing method of the ink composition comprises following steps:

adding 9 g of the white-light block polymer obtained from embodiment 1 into 61 g of propyleneglycol monoethyl ether and stirring to obtain a first solution; and

adding 15 g of phenol and 15 g of ethanol into the first solution and mixing uniformly to obtain the ink composition.

### Embodiment 4

The embodiment provides an ink composition. The ink composition comprises 5 g of the white-light block polymer obtained from embodiment 1, 75 g of ethylene glycol monobutyl ether acetate, 10 g of hydroquinone, and 10 g of propanol.

The manufacturing method of the ink composition comprises following steps:

adding 5 g of the white-light block polymer obtained from embodiment 1 into 75 g of ethylene glycol monobutyl ether acetate and stirring to obtain a first solution; and

adding 10 g of hydroquinone, and 10 g of propanol into the first solution and mixing uniformly to obtain the ink composition.

### Embodiment 5

The embodiment provides an ink composition. The ink composition comprises 0.01 g of the white-light block polymer obtained from embodiment 1, 85 g of ethylene glycol monobutyl ether acetate, 5 g of hydroquinone, and 9.99 g of triethylamine.

The manufacturing method of the ink composition comprises following steps:

adding 0.01 g of the white-light block polymer obtained from embodiment 1 into 85 g of ethylene glycol monobutyl ether acetate and stirring to obtain a first solution; and

adding 5 g of hydroquinone, and 9.99 g of triethylamine into the first solution and mixing uniformly to obtain the ink composition.

### Embodiment 6

The embodiment provides an ink composition. The ink composition comprises 3 g of the white-light block polymer obtained from embodiment 1, 85 g of durene, 6 g of imidazole, and 6 g of ethylenediamine.

The manufacturing method of the ink composition comprises following steps:

adding 3 g of the white-light block polymer obtained from embodiment 1 into 85 g of durene and stirring to obtain a first solution; and

adding 6 g of imidazole and 6 g of ethylenediamine into the first solution and mixing uniformly to obtain the ink composition.

The above ink compositions in embodiments 2 to 6 form ink droplets by inkjet printing, and after forming a film by vacuum drying, solvents are further removed by heat treatment in air to form a white-light organic light-emitting layer. The white organic light-emitting layer matched with a red color filter, a blue color filter, and a green color filter can emit red, blue, and green light, respectively, without needing to manufacture an organic film layer corresponding to different colors of light by inkjet printing, which simplifies printing processing and prevents pixels having different colors of light from crosstalking.

The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

1. A white-light block polymer, comprising a yellow-light block or/and a red-light block and a green-light block, and a blue-light block;
wherein the blue-light block is at least one selected from the group consisting of polyfluorene, polyfluorene derivatives, polybenzene, polybenzene derivatives, polycarbazole, and polycarbazole derivatives, the yellow-light block is at least one selected from the group consisting of polybenzothiadiazole and poly(phenylene vinylene), the red-light block is poly(dithiophenebenzothiadiazole), and the green-light block is at least one selected from the group consisting of polybenzothiadiazole and poly(phenylene vinylene).

2. The white-light block polymer according to claim 1, having a structure shown in a following formula (1), 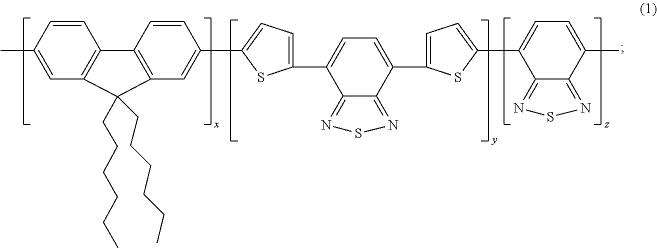
wherein x, y, and z are molar ratios of corresponding polymer main chains to the white-light block polymer, x, y, and z are greater than 0 and less than 1, and x, y, and z satisfy formulas x+y+z=1 and y=x+z.

3. The white-light block polymer according to claim 2, wherein x:y:z=(0.35-0.45):0.5:(0.05-0.15).

4. The white-light block polymer according to claim 3, wherein x:y:z=0.4:0.5:0.1.

5. The white-light block polymer according to claim 2, wherein number average molecular weight of the white-light block polymer ranges from 1000 to 10000.

6. An ink composition, wherein according to percentages by weight, the ink composition comprises:
0.001% to 10% of a white-light block polymer having a structure shown in a following formula (1), 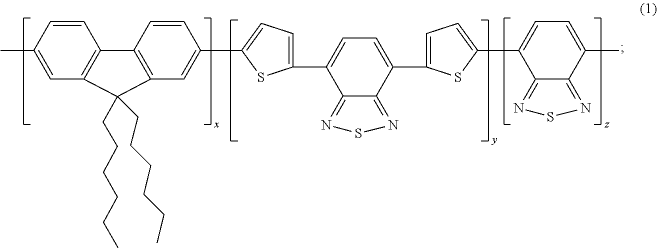
60% to 90% of an organic solvent;
0.01% to 15% of a surface tension modifier; and
0.01% to 15% of a viscosity modifier;
wherein x, y, and z are molar ratios of corresponding polymer main chains to the white-light block polymer, x, y, and z are greater than 0 and less than 1, and x, y, and z satisfy formulas x+y+z=1 and y=x+z.

7. The ink composition according to claim 6, wherein according to percentages by weight, the ink composition comprises:
0.01% to 5% of the white-light block polymer;
75% to 85% of the organic solvent;
0.1% to 10% of the surface tension modifier; and
0.1% to 10% of the viscosity modifier.

8. The ink composition according to claim 6, wherein the organic solvent is at least one selected from the group consisting of ethylene glycol monobutyl ether acetate, propyleneglycol monoethyl ether, and durene.

9. The ink composition according to claim 6, wherein the surface tension modifier is at least one selected from the group consisting of imidazole, imidazole derivatives, phenol, and hydroquinone.

10. The ink composition according to claim 6, wherein the viscosity modifier is at least one selected from the group consisting of alcohols, ethers, esters, and organic amines.

11. A manufacturing method of an ink composition, comprising following steps:
dissolving 0.001 wt % to 10 wt % of the white-light block polymer described in claim 2 into 60 wt % to 90 wt % of an organic solvent to obtain a first solution; and
adding 0.01 wt % to 15 wt % of a surface tension modifier and 0.01 wt % to 15 wt % of a viscosity modifier into the first solution and mixing uniformly to obtain the ink composition.

12. The manufacturing method of the ink composition according to claim 11, comprising following steps:
dissolving 0.01 wt % to 5 wt % of the white-light block polymer in into 75 wt % to 85 wt % of the organic solvent to obtain the first solution; and
adding 0.1 wt % to 10 wt % of the surface tension modifier and 0.1 wt % to 10 wt % of the viscosity modifier into the first solution and mixing uniformly to obtain the ink composition.

13. The manufacturing method of the ink composition according to claim 11, wherein the organic solvent is at least one selected from the group consisting of ethylene glycol monobutyl ether acetate, propyleneglycol monoethyl ether, and durene.

14. The manufacturing method of the ink composition according to claim 11, wherein the surface tension modifier is at least one selected from the group consisting of imidazole, imidazole derivatives, phenol, and hydroquinone.

15. The manufacturing method of the ink composition according to claim 11, wherein the viscosity modifier is at least one selected from the group consisting of alcohols, ethers, esters, and organic amines.
